(19) United States
(12) Patent Application Publication
(10) Pub. No.: US 2017/0205712 A1
(43) Pub. Date: Jul. 20, 2017

(54) DEVELOPMENT APPARATUS AND METHOD FOR DEVELOPING PHOTORESIST LAYER ON WAFER USING THE SAME

(71) Applicant: Micron Technology, Inc., Boise, ID (US)

(72) Inventor: Kuo-Yao Chou, Taichung City (TW)

(21) Appl. No.: 15/001,267

(22) Filed: Jan. 20, 2016

(51) Int. Cl. G03F 7/16

(52) U.S. Cl. CPC G03F 7/16

(57) ABSTRACT

A development apparatus includes a rotatable table for mounting a wafer, and a shower nozzle positioned directly above the rotatable table. The shower nozzle comprises a housing having a liquid inlet and a nozzle plate. The nozzle plate has a plurality of apertures distributed on a major surface of the nozzle plate. Solvent or water is uniformly dispensed onto the wafer through the apertures.

### BACKGROUND OF THE INVENTION

1. Field of the Invention

The present invention relates to a development method and an apparatus. More particularly, the present invention relates to a shower nozzle equipped in a development apparatus, which is capable of improving wafer-to-wafer uniformity of development.

2. Description of the Prior Art

The fabrication of an integrated circuit (IC) requires a variety of physical and chemical processes performed on a semiconductor (e.g., silicon) substrate. In general, the various processes used to make an IC fall into three categories: film deposition, patterning, and semiconductor doping. Films of both conductors (such as polysilicon, aluminum, and more recently copper) and insulators (various forms of silicon dioxide, silicon nitride, and others) are used to connect and isolate transistors and their components. Selective doping of various regions of silicon allows the conductivity of the silicon to be changed with the application of voltage. By creating structures of these various components millions of transistors can be built and wired together to form the complex circuitry of a modern microelectronic device. Fundamental to all of these processes is lithography, i.e., the formation of three-dimensional relief images on the substrate for subsequent transfer of the pattern to the substrate.

To build the complex structures that make up a transistor and the many wires that connect the millions of transistors of a circuit, lithography and etch pattern transfer steps are repeated at least 20 to 30 times to make one circuit. Each pattern being printed on the wafer is aligned to the previously formed patterns and slowly the conductors, insulators, and selectively doped regions are built up to form the final device.

Optical lithography is basically a photographic process by which a light sensitive polymer, called a photoresist, is exposed and developed to form three-dimensional relief images on the substrate. In general, the ideal photoresist image has the exact shape of the designed or intended pattern in the plane of the substrate, with vertical walls through the thickness of the resist. Thus, the final resist pattern is binary: parts of the substrate are covered with resist while other parts are completely uncovered. This binary pattern is needed for pattern transfer since the parts of the substrate covered with resist will be protected from etching, ion implantation, or other pattern transfer mechanism. The general sequence of processing steps for a typical photolithography process is as follows: substrate preparation, photoresist spin coat, prebake, exposure, post-exposure bake, development, and postbake. A resist strip is the final operation in the lithographic process, after the resist pattern has been transferred into the underlying layer.

Once exposed, the photoresist must be developed. Most commonly used photoresists use aqueous bases as developers. In particular, tetramethyl ammonium hydroxide (TMAH) is used in concentrations of 0.2-0.26 N. Development is undoubtedly one of the most critical steps in the photoresist process. The characteristics of the resist-developer interactions determine to a large extent the shape of the photoresist profile and, more importantly, the linewidth control.

Different developer application techniques are commonly used. For example, during spin development, wafers are spun, using equipment similar to that used for spin coating, and developer is poured onto the rotating wafer. The wafer is also rinsed and dried while still spinning. Spray development has been shown to have good results using developers specifically formulated for this dispense method. Using a process identical to spin development, the developer is sprayed, rather than poured, on the wafer by using a nozzle that produces a fine mist of developer over the wafer. This technique reduces developer usage and gives more uniform developer coverage. Another in-line development strategy is called puddle development. Again using developers specifically formulated for this process, the developer is poured onto a stationary wafer that is then allowed to sit motionless for the duration of the development time. The wafer is then spin-rinsed and dried.

There is always a need in this technical filed to pursue a higher level of development uniformity.

### SUMMARY OF THE INVENTION

The present invention has been made in view of the above-described actual situation, and its object is to provide an improved development apparatus that features excellent development efficiency, resource saving, and higher uniformity.

To achieve the objects described above, the present invention is configured as follows. A development apparatus includes a rotatable table for mounting a wafer, and a shower nozzle positioned directly above the rotatable table. The shower nozzle comprises a housing having a liquid inlet and a nozzle plate. The nozzle plate has a plurality of apertures distributed on a major surface of the nozzle plate. Solvent or water is uniformly dispensed onto the wafer through the apertures.

According to another aspect of the invention, a method for developing a photoresist layer on a wafer is disclosed. A wafer having an imaged photoresist layer is mounted on the rotatable table of the development apparatus. The shower nozzle is positioned directly above the rotatable table and the wafer. A puddle of developer is dispensed onto a top surface of the photoresist layer through the plurality of apertures. The imaged photoresist layer is then developed for a given length of time. The puddle of developer is then spun off. The wafer is spin-rinsed with deionized (DI) water. The DI water is uniformly dispensed onto the wafer through the plurality of apertures. The wafer is then spin-dried.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The above and other aspects and features of the present invention will become apparent by describing in detail exemplary embodiments thereof with reference to the attached drawings, in which:

FIG. 1 is a schematic diagram showing an exemplary development apparatus according to one embodiment of the invention;

FIG. 2 is a plan view of a major surface of a shower nozzle on which a plurality of apertures is distributed; and

FIG. 3 to FIG. 8 are schematic diagrams showing an exemplary method for developing a photoresist layer on a wafer.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. It will, however, be apparent to one skilled in the art that the invention may be practiced without these specific details. Furthermore, some well-known system configurations and process steps are not disclosed in detail, as these should be well-known to those skilled in the art.

Likewise, the drawings showing embodiments of the apparatus are semi-diagrammatic and not to scale and some dimensions are exaggerated in the figures for clarity of presentation. Also, where multiple embodiments are disclosed and described as having some features in common, like or similar features will usually be described with like reference numerals for ease of illustration and description thereof.

The present invention pertains to a development apparatus. The disclosed development apparatus may be employed in an in-line wafer processing system for developing an imaged photoresist layer on a wafer, but is not limited thereto. For the sake of simplicity, only the germane parts of the apparatus are shown in the figures. Other elements, for example, draining parts, detectors, motor, or the like, are believed known in the art and are therefore not shown in the figures. It is also known that a standard photolithography process flow generally includes coating, exposure and development of the photosensitive material (photoresist).

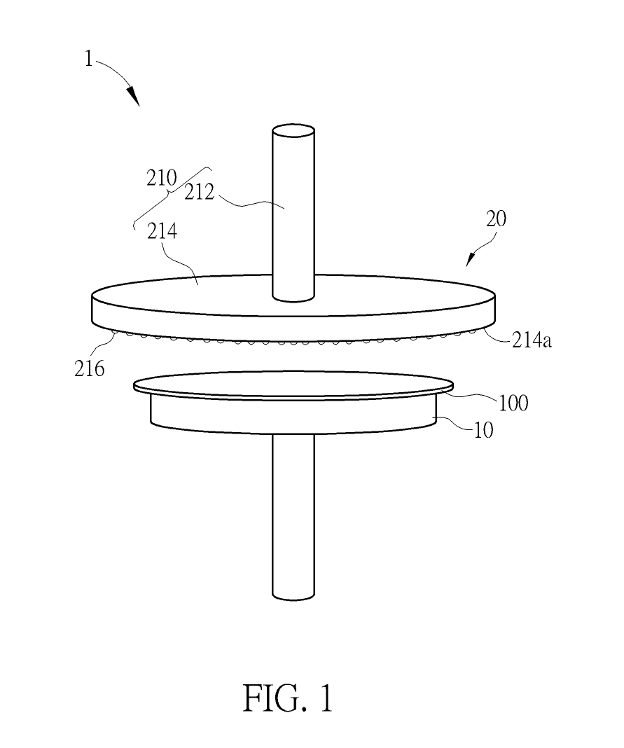

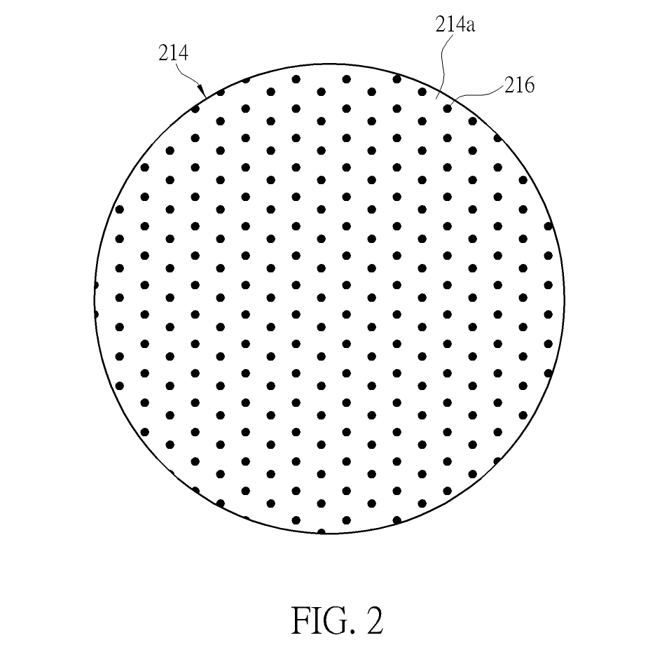

Please refer to FIG. 1 and FIG. 2. FIG. 1 is a schematic diagram showing an exemplary development apparatus according to one embodiment of the invention. FIG. 2 is a plan view of a major surface of a shower nozzle on which a plurality of apertures is distributed. As shown in FIG. 1, the development apparatus 1 comprises a rotatable table 10 for mounting a wafer 100, and a shower nozzle 20 positioned directly above the rotatable table 10. The shower nozzle 20 comprises a housing 210 having a liquid inlet 212 and a nozzle plate 214. The nozzle plate 214 has a plurality of apertures 216 distributed on a major surface 214a of the nozzle plate 214. The liquid inlet 212 of the housing 210 is in fluid communication with the apertures 216 to provide a plurality of liquid outlets.

Through the shower nozzle 20 and the apertures 216, solvent such as a developer or water such as deionized (DI) water can be uniformly dispensed onto the wafer. According to the embodiment, the aforesaid developer may comprise tetramethylammonium hydroxide (TMAH) or diluted TMAH, but is not limited thereto.

According to the embodiment, the apertures 216 are evenly distributed across the entire major surface 214a of the nozzle plate 214. However, in some embodiments, the apertures 216 may not be evenly distributed across the entire major surface 214a of the nozzle plate 214. The arrangement of the apertures 216 depends upon the design requirements.

According to the embodiment, the apertures 216 have the same diameter. However, in some embodiments, the apertures 216 may have different diameters. The diameters of the apertures 216 depend upon the design requirements.

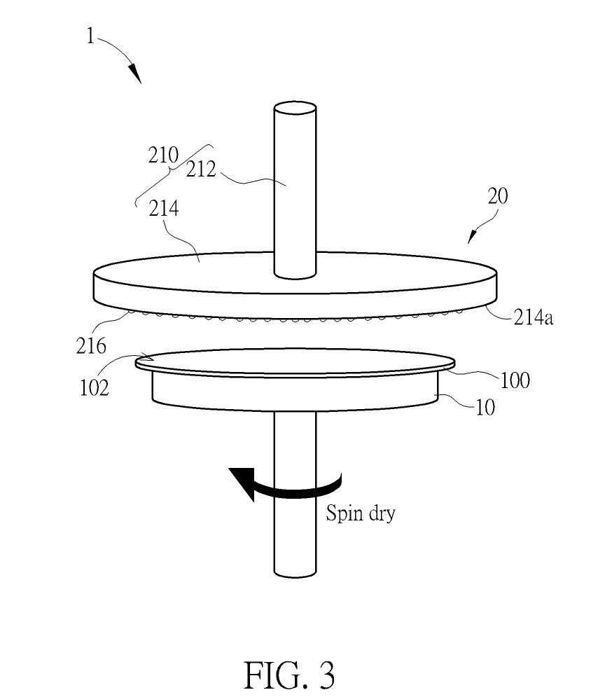

Please refer to FIG. 3 to FIG. 8. FIG. 3 to FIG. 8 are schematic diagrams showing an exemplary method for developing a photoresist layer on a wafer, wherein like numeral numbers designate like elements, layers, or regions. First, as shown in FIG. 3, a wafer 100 having an imaged photoresist layer 102 is mounted on the rotatable table 10 of the development apparatus 1 as described in FIG. 1. The imaged photoresist layer 102 comprises an image of pattern (latent pattern) according to a predetermined photomask, which is formed during an exposure process.

According to the embodiment, the shower nozzle 20 comprises a housing 210 having a liquid inlet 212 and a nozzle plate 214. The nozzle plate 214 has a plurality of apertures 216 distributed on a major surface 214a of the nozzle plate 214. Solvent or water is uniformly dispensed onto the wafer 100 through the apertures 216.

According to the embodiment, optionally, the photoresist layer 102 may be pre-wetted by dispensing DI water onto the photoresist layer 102 through the plurality of apertures 216. Subsequently, the photoresist layer is spin-dried. It is understood that the pre-treatment of the photoresist layer 102 may be omitted.

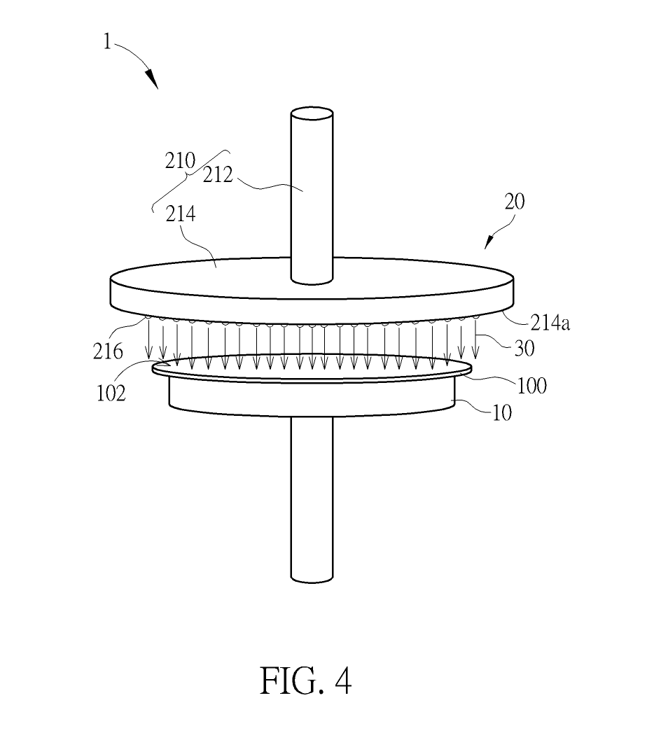

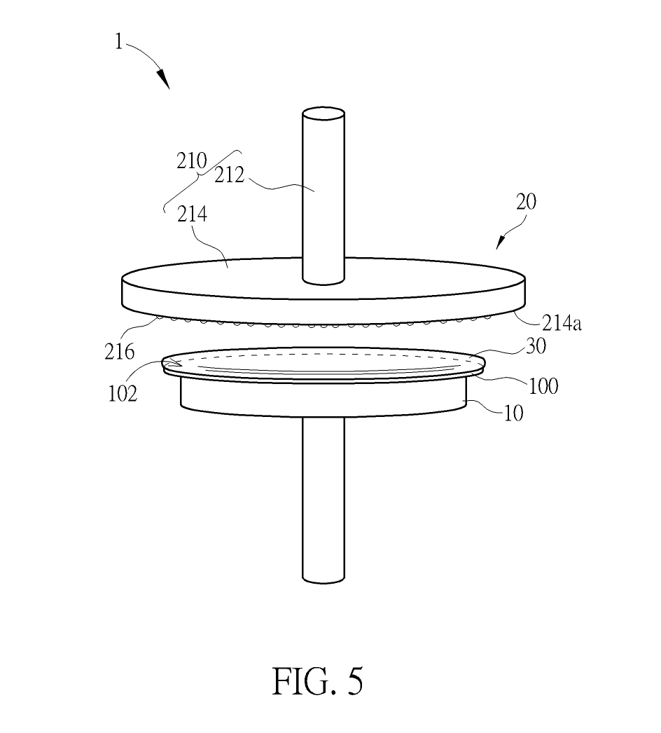

As shown in FIG. 4 and FIG. 5, subsequently, a puddle of developer 30 is uniformly dispensed onto a top surface of the photoresist layer 102 through the plurality of apertures 216. According to the embodiment, the developer may comprise tetramethylammonium hydroxide (TMAH) or diluted TMAH, but is not limited thereto. It is understood that other developer may be used. The developer is a chemical used to selectively dissolve resist (photoresist) as a function of its chemical composition. A development process is then carried out at a controlled temperature. The development time may be optimized in order to obtain the best performance for the photoresist layer 102.

According to the embodiment, optionally, after dispensing the puddle of developer 30 onto the top surface of the photoresist layer 102 through the plurality of apertures 216, the wafer 100 may be rotated at a spin rate for a time period.

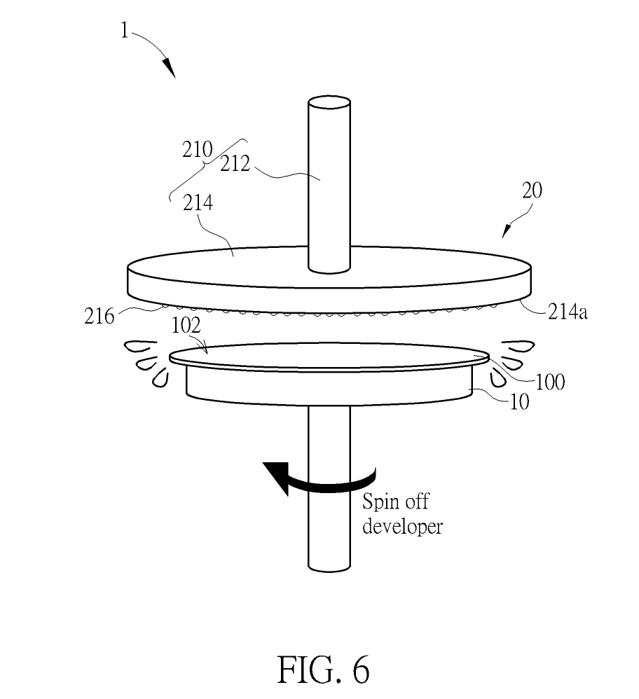

As shown in FIG. 6, after the development of the photoresist layer 102 is completed, the puddle of developer 30 is spun off the wafer surface.

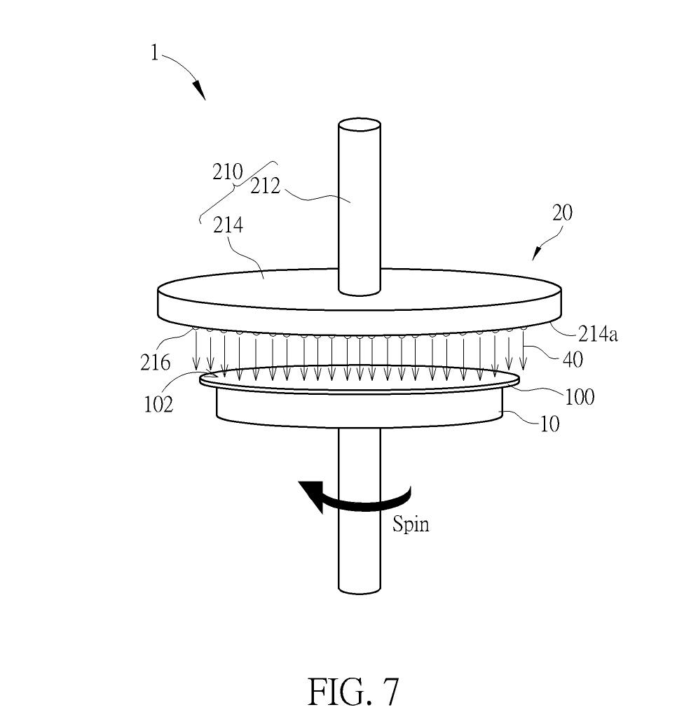

As shown in FIG. 7, DI water rinse process is then performed. According to the embodiment, DI water 40 is dispensed onto the developed photoresist layer 102 through the plurality of apertures 216. The DI water rinse serves two functions: to stop development and to remove particles generated during the development process. Optionally, the wafer 100 may be spun during the rinse so that centrifugal force can assist in removing particles.

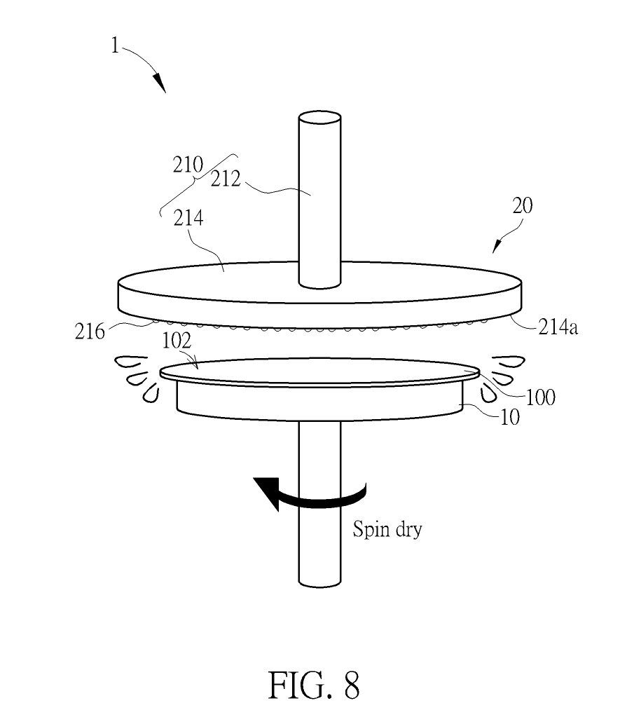

Finally, as shown in FIG. 8, the wafer 100 is spin-dried. Subsequently, the wafer 100 is dismounted from the rotatable table and is removed from the development apparatus 1 for the following processes.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A development apparatus, comprising:
a rotatable table for mounting a wafer; and
a shower nozzle positioned directly above the rotatable table, wherein said shower nozzle comprises a housing having a liquid inlet and a nozzle plate, wherein said nozzle plate has a plurality of apertures distributed on a major surface of said nozzle plate.

2. The development apparatus according to claim 1, wherein said liquid inlet of said housing is in fluid communication with said apertures to provide a plurality of liquid outlets.

3. The development apparatus according to claim 1, wherein solvent or water is uniformly dispensed onto said wafer through the apertures.

4. The development apparatus according to claim 3, wherein said solvent comprises a developer.

5. The development apparatus according to claim 4, wherein said developer comprises tetramethylammonium hydroxide (TMAH).

6. The development apparatus according to claim 3, wherein said water comprises deionized water.

7. The development apparatus according to claim 1, wherein said apertures are evenly distributed across entire said major surface of said nozzle plate.

8. The development apparatus according to claim 1, wherein said apertures have the same diameter.

9. The development apparatus according to claim 1, wherein said apertures have different diameters.

10. A method for developing a photoresist layer on a wafer, comprising:
providing a wafer having an imaged photoresist layer;
mounting said wafer on a rotatable table of a development apparatus, wherein the development apparatus is equipped with a shower nozzle positioned directly above the rotatable table and the wafer, wherein said shower nozzle comprises a housing having a liquid inlet and a nozzle plate, wherein said nozzle plate has a plurality of apertures distributed on a major surface of said nozzle plate;
dispensing a puddle of developer onto a top surface of said photoresist layer through said plurality of apertures;
developing the imaged photoresist layer;
spinning off said puddle of developer;
spin rinsing said wafer with deionized (DI) water through said plurality of apertures; and
spin drying said wafer.

11. The method for developing a photoresist layer on a wafer according to claim 10, wherein after dispensing said puddle of developer onto said top surface of said photoresist layer through said plurality of apertures, the method further comprises:
rotating said wafer at a spin rate for a time period.

12. The method for developing a photoresist layer on a wafer according to claim 10, wherein before dispensing said puddle of developer onto said top surface of said photoresist layer through said plurality of apertures, the method further comprises:
pre-wetting said photoresist layer by dispensing DI water onto said photoresist layer through said plurality of apertures; and
spin drying said photoresist layer.

13. The method for developing a photoresist layer on a wafer according to claim 10, wherein after spin drying said wafer, the method further comprises:
dismounting said wafer.

14. The method for developing a photoresist layer on a wafer according to claim 10, wherein said liquid inlet of said housing is in fluid communication with said apertures to provide a plurality of liquid outlets.

15. The method for developing a photoresist layer on a wafer according to claim 10, wherein said puddle of developer is uniformly dispensed onto said wafer through the apertures.

16. The method for developing a photoresist layer on a wafer according to claim 10, wherein said puddle of developer comprises tetramethylammonium hydroxide (TMAH).
